(19) United States
(12) Patent Application Publication
(10) Pub. No.: US 2025/0037981 A1
(43) Pub. Date: Jan. 30, 2025

(54) SYSTEMS AND METHODS FOR DEPOSITING METAL

(71) Applicant: Tokyo Electron Limited, Tokyo (JP)

(72) Inventors: David Eitan Barlaz, Albany, NY (US); Joshua Baillargeon, Albany, NY (US)

(21) Appl. No.: 18/359,275

(22) Filed: Jul. 26, 2023

(51) Int. Cl. H01J 37/34; C23C 14/35; H01L 21/033; H01L 21/768

(52) U.S. Cl. CPC H01J 37/3467; C23C 14/35; H01J 37/3405; H01L 21/033; H01L 21/76877; H01J 2237/0473; H01J 2237/332

(57) ABSTRACT

An embodiment method includes depositing, in a processing chamber of a high-power impulse magnetron sputtering system, a metal containing layer over a substrate. The depositing includes applying a cyclic plurality of pulses. Each cycle includes applying a primary negative pulse on a target electrode to dislodge target atoms from the target electrode and a secondary positive pulse to accelerate the dislodged target atoms towards the substrate. The secondary positive pulse in one of the cycles is different from the secondary positive pulse in another one of the cycles.

### TECHNICAL FIELD

The present invention relates generally to a system and method for semiconductor processing, and, in particular embodiments, to systems and methods for depositing metal.

### BACKGROUND

Dimension shrinkage is one of the driving forces in the development of integrated circuit processing. By reducing the size dimensions, cost-benefit and device performance boosts can be obtained. This scalability creates inevitable complexity in process flow, especially on patterning techniques. For example, as smaller circuits such as transistors are manufactured, the critical dimension (CD) or resolution of patterned features is becoming more challenging to produce, particularly in high volume. Patterning of features in a semiconductor device often includes formation of a hardmask that may be patterned and used in an etching process. Amorphous carbon is an example of a typical material for a hardmask for manufacturing devices having a high aspect ratio; however, amorphous carbon has somewhat poor etch selectivity and thus may not be an ideal hardmask material for manufacture of some semiconductor devices.

### SUMMARY

A method includes depositing, in a processing chamber of a high-power impulse magnetron sputtering system, a metal containing layer over a substrate. The depositing includes applying a cyclic plurality of pulses. Each cycle includes applying a primary negative pulse on a target electrode to dislodge target atoms from the target electrode and a secondary positive pulse to accelerate the dislodged target atoms towards the substrate. The secondary positive pulse in one of the cycles is different from the secondary positive pulse in another one of the cycles.

A method for manufacturing a semiconductor structure includes positioning a substrate into a plasma processing chamber of a high-power impulse magnetron sputtering system. The substrate includes a layer stack of alternating layers. The method includes forming a hard mask layer over a surface of the layer stack, where the forming includes generating a first pulse having a first polarity; and driving ions of a metal target to the surface of the substrate by generating a second pulse having a second polarity opposite the first polarity.

A high-power impulse magnetron sputtering (HiPIMS) system includes a plasma processing chamber; and a substrate support in the plasma processing chamber. The substrate support is configured to hold a semiconductor substrate. The HiPIMS system includes pulse generation circuitry configured to supply positive and negative electrical pulses to the plasma processing chamber; and processing circuitry configured to apply a cyclic plurality of electrical pulses to a target electrode. Each cycle includes a primary negative pulse to dislodge target atoms from the target electrode and a secondary positive pulse to accelerate the dislodged target atoms towards the substrate support, where the processing circuitry configured to vary a pulse parameter of a secondary positive pulse in one of the cycles to a pulse parameter of a secondary positive pulse in another one of the cycles.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a schematic diagram illustrating a high-power impulse magnetron sputtering (HIPIMS) system, in accordance with some embodiments;

FIGS. 1B-1C illustrate pulses applied during a HIPIMS process in accordance with some embodiments;

FIG. 1D illustrates the resultant potential applied at the target electrode;

FIG. 2 is a schematic diagram illustrating a system for generating high-voltage pulses which may be included as part of the HiPIMS system, in accordance with some embodiments;

FIG. 3 is a structure zone diagram illustrating a relationship between stresses of a layer formed in a HiPIMS system and temperature, energy, and film thickness, in accordance with some embodiments;

FIG. 4A is a flow chart illustrating a method of forming a hardmask layer having controlled stress, in accordance with some embodiments;

FIG. 4B illustrate a cross-sectional view of a substrate having formed a hardmask layer in accordance with some embodiments;

FIG. 5 is a flow chart illustrating a method for manufacturing a semiconductor structure having a mask layer, in accordance with some embodiments;

FIG. 6A is a schematic diagram of a semiconductor device fabricated in accordance with some embodiments;

FIGS. 6B-6E illustrate cross-sectional views of a semiconductor device during various stages of fabrication in accordance with embodiments;

FIG. 7 illustrates a flow chart illustrating a method for depositing a metal containing layer over a substrate in accordance with an embodiment; and

FIG. 8 illustrates a flow chart illustrating a method for depositing a hard mask layer over a layer stack in accordance with an embodiment.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

According to one or more embodiments of the present disclosure, this application relates to HiPIMS systems and methods of forming metal-containing hardmask layers on a semiconductor substrate with a controlled or desired stress profile. As noted previously herein, amorphous carbon is a typical material for hard mask layers for devices having a high aspect ratio; however, amorphous carbon has poor etch selectivity. Metal containing materials may be used as an alternative to amorphous carbon; however, some metal containing hardmasks, such as a tungsten silicide (WSi) film, may normally form with intrinsic stresses that may cause bowing or warping of the semiconductor wafer especially as the thickness of the metal containing hard masks are increased to account for etching high aspect ratio features. In accordance with one or more embodiments of the present disclosure, HiPIMS systems and methods are provided in which the stress of a metal-containing hardmask layer is controlled during deposition by controlling the energy of an ion beam of the HiPIMS system, for example, utilizing negative voltage primary pulses and positive voltage secondary pulses.

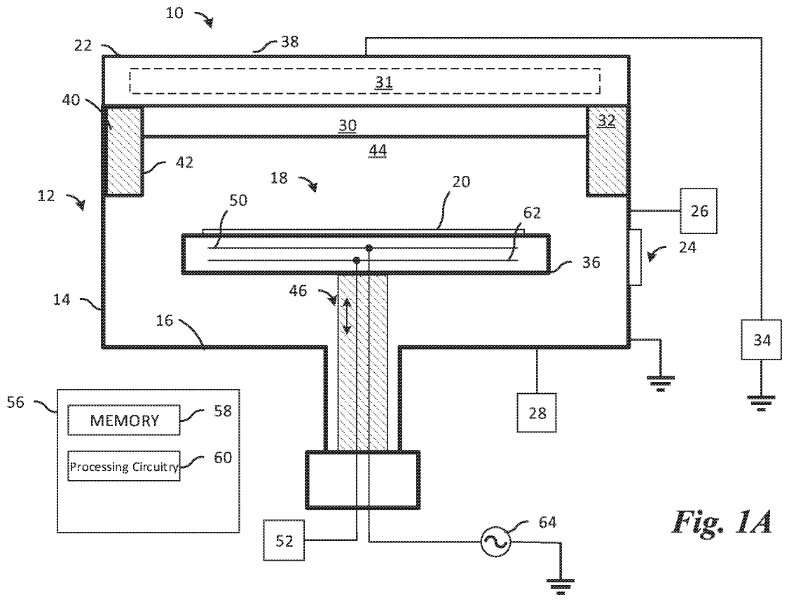

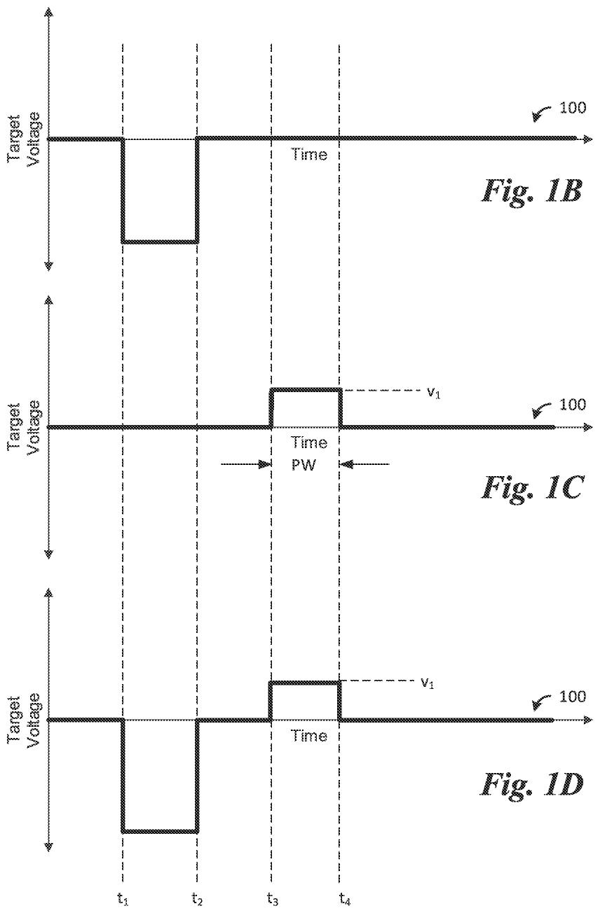

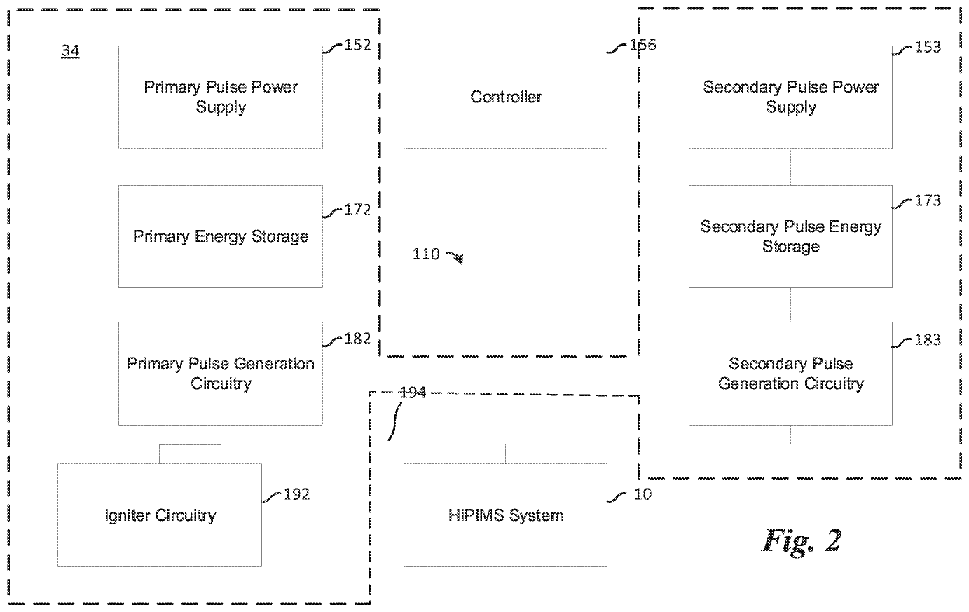

FIG. 1A is a schematic diagram illustrating a high-power impulse magnetron sputtering (HiPIMS) system 10, in accordance with one or more embodiments.

The HiPIMS system 10 includes a plasma processing chamber 12 that at least partially defines a processing volume 18, it should be noted that this figure depicts a single magnetron case but it is possible to have a configuration with multiple magnetrons. The plasma processing chamber 12 includes sidewalls 14 and a bottom wall 16. The plasma processing chamber 12, including the sidewalls 14 and bottom wall 16, may have various dimensions and proportions in various embodiments, which may be selected according to design preferences, for example, depending on a size of a semiconductor substrate 20 to be processed in the HiPIMS system 10. The semiconductor substrate 20 may have any size or dimensions. Examples of suitable semiconductor substrate 20 sizes include 200 mm diameter, 300 mm diameter, 450 mm diameter or larger.

The semiconductor substrate 20 may be or include any semiconductor material. In some embodiments, the semiconductor substrate 20 may be a silicon substrate, a silicon carbide (SiC) substrate, a gallium arsenide (GaAs) substrate as well as heterostructures such a gallium nitride (GaN) on silicon substrate, semiconductor on insulator (SOI), or any other semiconductor substrate.

The HiPIMS system 10 includes a lid 22, which may be attached to the chamber 12, for example, at a top of the chamber 12. In some embodiments, the chamber 12 may be formed of a metal, such as aluminum; however, embodiments are not limited thereto and in various embodiments, the chamber 12 may be formed of any suitable materials. The walls of the chamber 12 may be coated with an inert material to minimize corrosion from the plasma.

The HiPIMS system 10 may further include a substrate loading port 24 configured to receive the semiconductor substrate 20. The substrate loading port 24 may be formed or disposed at any suitable position on the chamber 12, and in some embodiments, the substrate loading port 24 is formed extending through a sidewall 14 of the chamber 12. The substrate loading port 24 may be utilized to move the semiconductor substrate 20 into and out of the chamber 12, for example, before and after a deposition process performed by the HiPIMS system 10. In some embodiments, the substrate loading port 24 may be coupled to a transfer chamber or other chambers of a semiconductor substrate processing system. In some embodiments, the semiconductor substrate 20 may be transferred into and out of the chamber 12 by a robot arm or any other suitable transport mechanism. In some embodiments, the HiPIMS system 10 includes a chuck or substrate support 36 that is configured to hold or support the semiconductor substrate 20 in the chamber 12 during processing.

The HiPIMS system 10 may further include a gas source 26. The gas source 26 may be coupled to the plasma processing chamber 12 and configured to supply one or more gases into the processing volume 18. The process gases may include any gases suitable for processing the semiconductor substrate 20, for example, by deposition or other process techniques. In some embodiments, the process gases may include one or more of inert gases, non-reactive gases, and reactive gases. Examples of process gases that may be provided by the gas source 26 include, but are not limited to, argon gas (Ar), helium (He), neon gas (Ne), krypton (Kr), xenon (Xe), nitrogen gas (N2), oxygen gas (O2), hydrogen gas (H2), forming gas (N2+H2), ammonia (NH3), methane (CH4), carbon monoxide (CO), and carbon dioxide (CO2). In the case that the deposited film is not pure metal, any suitable precursor gases may be introduced via the gas source 26 as a mixture. For example, if a metal silicide was to be deposited, silane (SiH4) or silicon tetrachloride (SiCl4) may be mixed with a sputtering gas such as argon.

In some embodiments, the HiPIMS system 10 may include a pump 28 which may be coupled (e.g., in fluid communication with) to the chamber 12. For example, in some embodiments, the pump 28 may be coupled to the chamber 12 by one or more lines which extend through the bottom wall 16 of the chamber 12. The pump 28 may be coupled to the processing volume 18. During processing, the pump 28 may be utilized to evacuate and control the pressure in the processing volume 18. In various embodiments, the pressure in the processing volume 18 may be maintained in a range between about 1 mTorr to about 500 mTorr during processing of the semiconductor substrate 20. In some embodiments, the pressure in the processing volume 18 may be maintained over a range between about 1 mTorr and about 50 mTorr. The pump 28 may maintain the pressure in the processing volume 18 at any suitable level, for example, depending on design preferences, materials to be deposited on the semiconductor substrate 20, dimensions (e.g., thickness) of a layer to be formed on the semiconductor substrate 20, or any other desired parameters during processing of the semiconductor substrate 20 in the HiPIMS system 10.

In some embodiments, the lid 22 includes a target 30 and a ground shield assembly 32 coupled thereto. The target 30 provides a material source that can be sputtered and deposited onto the surface of the semiconductor substrate 20 during a PVD process performed by the HiPIMS system 10. In some embodiments, the target 30 serves as a cathode for generating a plasma by the HiPIMS system 10, e.g., during sputter deposition to form one or more layers on the semiconductor substrate 20. In some embodiments, the target 30 serves as a positive electrode during the HiPIMS discharge's positive cycle.

The target 30 may include any material suitable for depositing a desired layer on the semiconductor substrate 20. In some embodiments, the target 30 may be formed of a material that is to be deposited on the semiconductor substrate 20. In some embodiments, the target 30 may be formed of a material that is included as an element of the layer to be deposited on the semiconductor substrate 20. In some embodiments, the target 30 may be formed of or include a metal that is included in the layer that is deposited on the semiconductor substrate 20 during processing in the HiPIMS system 10. In various embodiments, the HiPIMS system 10 may be utilized to form metal or metal-containing films, which in some embodiments may be a tungsten silicide (WSi) film. For example, in some embodiments, the target 30 may be formed of or include tungsten (W) and the HiPIMS system 10 may be configured to deposit a tungsten silicide (WSi) film on the semiconductor substrate 20. In various embodiments, the target 30 may include any metal material, such as Aluminum (Al), Tin (Sn), Titanium (Ti), Tantalum (Ta), Cobalt (Co), Molybdenum (Mo), Copper (Cu), Zirconium (Zr), or any other metal material suitable for sputter deposition during operation of the HiPIMS system 10.

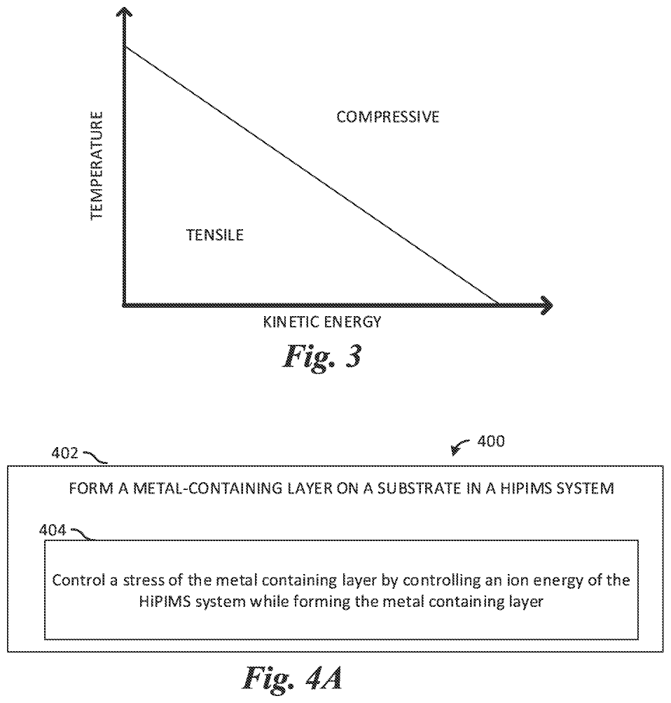

In some embodiments, the HiPIMS system 10 may include a power source 34, which in some embodiments may be a high voltage power supply and will be described in more detail in FIG. 2. The power source 34 may be electrically coupled or connected to the target 30, and may be configured to cause materials from the target 30 to be sputtered so as to deposit a layer on the semiconductor substrate 20 during operation of the HiPIMS system 10. In some embodiments, the power source 34 may be configured to supply pulsed power to the target 30. For example, the power source 34 may provide a series of electrical pulses to the target 30, in some embodiments.

In some embodiments, the target 30 may extend over the sidewalls 14 of the chamber 12, and may be mechanically coupled to the sidewalls 14. For example, peripheral portions or edges of the target 30 may be attached or otherwise secured to the sidewalls 14 of the chamber 12. In some embodiments, the target 30 may have a curved surface, for example, in a central region of the target 30. The curved surface may curve outward, for example, toward an upper surface of the semiconductor substrate 20. In some embodiments, the HiPIMS system 10 may be configured to maintain a desired spacing between the target 30 and the substrate support 36. For example, in some embodiments, the target 30 and substrate support 36 may be maintained at a distance between about 50 mm and about 300 mm. The target 30 may have various dimensions, shapes, materials, or the like which may be selected as desired, for example, depending on the layers to be deposited on the semiconductor substrate 20.

In some embodiments, the HiPIMS system 10 includes a top electrode 38 which may be utilized during processing of the semiconductor substrate 20. In some embodiments, the top electrode 38 may be included as part of the lid 22. In some embodiments, the top electrode 38 is a full face erosion magnetron cathode that is disposed overlying the target 30. In some embodiments, the top electrode 38 is disposed in contact with the target 30. The top electrode 38 may facilitate or enhance the sputtering of materials from the target 30 during processing in the HiPIMS system 10. In some embodiments, the top electrode 38 facilitates enhanced process control and formation of tailored film properties while also facilitating consistent erosion of the target 30 and uniform deposition across the semiconductor substrate 20.

In some embodiments, the top electrode 38 may be included as part of a magnetron assembly, which may be a linear magnetron, a serpentine magnetron, a spiral magnetron, a double-digitated magnetron, a rectangularized spiral magnetron, or any other magnetron shape suitable to form a desired erosion pattern on the face of the target 30 and to enable a desirable sheath formation during pulsed or DC plasma stages of processing in the HiPIMS system 10. In some embodiments, the magnetron may include permanent magnets that are positioned in a desired pattern over a surface of the target. In some embodiments, a variable magnetic field type magnetron having a desirable pattern may be included that may be used to adjust the shape or density of the plasma generated during processing in the HiPIMS system 10.

In various embodiments, the magnetron comprises a planar magnetron and may comprise, in an embodiment, a magnetic array 31 disposed along a magnetic plane parallel to the substrate support 36. The magnetic array 31 maybe rectangular or circular in various embodiments, and in various embodiments may comprise a concentric magnet pattern with a center having one pole and the perimeter having an opposite pole. An anode return electrode may be formed around the target electrode in some alternate embodiments. However, advantageously, in various embodiments, there is no separate return electrode as the chamber walls and substrate form the return electrode.

In some embodiments, the ground shield assembly 32 of the lid 22 may include a ground frame 40 and a ground shield 42, which may be configured to be the return electrode. In some embodiments, the ground shield 42 is coupled to the peripheral portion of the target 30 (e.g., via the ground frame 40), and the ground shield 42 and the target 30 may at least partially define an upper processing region 44 of the processing volume 18. For example, the upper processing region 44 may be a portion of the processing volume 18 that extends from a lower surface of the target 30 to the lower edges of the ground shield 42 in the processing volume 18. In some embodiments, the ground frame 40 electrically insulates the ground shield 42 from the target 30 while providing a ground path to the chamber 12 through the sidewalls 14. During processing of the semiconductor substrate 20 in the HiPIMS system 10, the ground shield 42 may constrain plasma generated within the upper processing region 44 and may dislodge target source material from the central portion of the target 30. Accordingly, the dislodged target source material may be deposited primarily on the surface of the semiconductor substrate 20, rather than on the sidewalls 14.

In some embodiments, the HiPIMS system 10 includes a shaft 46 that extends through the chamber 12, for example, through the bottom wall 16. The shaft 46 may be coupled to a lift assembly. In some embodiments, the lift assembly is configured to move the substrate support 36 (e.g., in a vertical direction) between a first position (e.g., a lower position) for transferring the semiconductor substrate 20 into or out of the chamber 12 via the loading port 24, and a second position (e.g., an upper position) in which the semiconductor substrate 20 is positioned in the processing volume 18 for processing.

In some embodiments, the substrate support 36 may be an electro-static chuck and have an electrode 50. In various embodiments, the substrate support 36 may be metallic or ceramic. In such embodiments, the electro-static substrate support 36 may be configured to hold semiconductor substrates 20 of either insulating or conducting types based on the attraction of opposite charges. In some embodiments, the substrate support 36 may be powered by a power supply 52, which may be a DC power supply. In some embodiments, the electrode 50 may be embedded within a dielectric material of the substrate support 36. The power supply 52 may provide a DC chucking voltage of about 200 to about 2000 volts to the electrode 50. In some embodiments, the power supply 52 may include a controller or control circuitry configured to control operation of the electrode 50 by directing a DC current to the electrode for chucking and de-chucking the semiconductor substrate 20.

During operation of the HiPIMS system 10, the process gases may be introduced into the chamber 12, for example, from the gas source 26, and the process gases may be energized to form a plasma that may be controlled to deposit a metal material, such as a tungsten silicide hard mask layer, on a surface of the semiconductor substrate 20 during HiPIMS processing.

Various embodiments may include other components for good deposition. For example, a frame may be disposed on or overlying the periphery of the substrate support 36, and the frame may be configured to confine deposition of source material sputtered from the target 30 to a desired portion of the substrate surface. As the substrate support 36 is raised to the upper position for processing (e.g., by moving the semiconductor substrate 20 into the processing volume 18), an outer edge of semiconductor substrate 20 that is disposed on the substrate support 36 may be engaged by the shadow frame.

In some embodiments, the HiPIMS system 10 includes a controller 56. The controller 56 is electrically coupled to the chamber 12 and is configured to control formation of a layer, such as a metal-containing hard mask layer, on the semiconductor substrate 20 during processing in the HiPIMS system 10. In some embodiments, the controller 56 includes processing circuitry 60 (which may be any circuitry configured to perform the various functions of the processing circuitry 60 described herein, and in some embodiments may be a central processing unit (CPU), a microprocessor, a microcontroller, multiple processors working together, or the like) and computer-readable memory 58. The controller 56 may be configured to control processing in the HiPIMS system 10, such as by controlling the process sequence, regulating the gas flows from the gas source 26 into the chamber 12, regulating power supply 52 and power source 34, and controlling ion bombardment of the target 30. In some embodiments, software instructions may be stored in the memory 58. The memory 58 may be any suitable computer-readable memory, and in some embodiments may be random access memory, read only memory, floppy or hard disk drive, or any other form of computer-readable storage media.

The processing circuitry 60 may be configured to execute one or more software instructions stored in the memory 58 in order to control processing of the semiconductor substrate 20 within the chamber 12 as described herein. For example, the processing circuitry 60 may be configured to execute the software instructions stored in the memory 58 to control or tune a stress of a layer (such as a metal-containing hard mask layer) that is formed on the semiconductor substrate 20 during processing in the HiPIMS system 10.

During processing, material is sputtered from the target 30 and deposited on the surface of the semiconductor substrate 20. In some embodiments, the target 30 is biased relative to ground or the substrate support 36, by the power source 34. The power source 34 may also provide power to generate and maintain a plasma formed from the process gases supplied by the gas source 26. In certain embodiments, the power to strike, generate, and maintain the plasma may be provided through other electrodes including the bottom electrode.

The ions generated in the plasma are accelerated towards and strike the target 30, causing target material to be dislodged from the target 30. The dislodged target material forms a layer on the semiconductor substrate 20 with a desired structure or composition. In various embodiments, the power source 34 may be an RF power supply, a DC power supply, a fast switching pulsed DC power supply, or any suitable power supply configured to provide tunable target bias for precise control of sputtering composition and deposition rates for the target material. Specifically, in various embodiments, the power source 34 supplies positive/negative DC pulses, including in combination with AC pulses or RF pulses. In an embodiment with multiple magnetrons, the power scheme for each magnetron can be independent or dependent. In an embodiment with multiple magnetrons, for example, the power scheme could have HiPIMS on one magnetron with DC power supplies or RF power supplies on the other magnetrons. In another embodiment with multiple magnetrons, the power scheme could have HiPIMS on all magnetrons, and in this case they can be synched (master/slave) or independent.

In some embodiments, the HiPIMS system 10 may be configured to separately apply a bias to the semiconductor substrate 20 during different phases of the deposition process. For example, in some embodiments, a bias may be provided to a bias electrode 62 (or chuck electrode 50) in the substrate support 36 from a power supply 64 (e.g., DC or RF source). The bias provided to the bias electrode 62 may cause the semiconductor substrate 20 to be bombarded with ions formed in the plasma during one or more phases of the deposition process. A larger negative substrate bias will tend to drive the positive ions generated in the plasma towards the substrate or vice versa, so that they have a larger amount of energy when they strike the substrate surface. However, as previously described, in various embodiments, the semiconductor substrate 20 may advantageously be coupled only to a reference potential or left floating and all the biasing is performed only through the power source 34. In other words, the biasing scheme may be applied to only the target 30. Having a single power source and eliminating the associated wiring to the chuck advantageously reduces the system cost and thus the fabrication costs.

In some embodiments, the power source 34 is a HiPIMS power supply configured to deliver power impulses to the target 30 with high current and high voltage over short durations within a range of frequencies. Performing the high-power impulse magnetron sputtering PVD processes in the HiPIMS system 10 with high current and high voltage pulses within a specific range of low pulse frequencies provided to a metal target, such as a Tungsten target.

FIGS. 1B-1C illustrate pulses applied during a HIPIMS process in accordance with some embodiments.

FIGS. 1B and 1C illustrate a primary pulse and a secondary pulse generated and applied at the target electrode during the deposition process in accordance with embodiments of the disclosure and FIG. 1D illustrates the resultant potential applied at the target electrode.

Referring to FIG. 1B, a primary negative pulse is applied that causes positively charged ions such as argon ions in the plasma to be accelerated towards the target electrode. In FIG. 1B-1D, the primary pulse is applied between the first time t1 and second time t2. The primary pulse has a high negative voltage. For example, in some embodiments, the high current densities and high voltage pulses may be in the range of between 0.1 A/cm² to 20 A/cm², e.g., 1 to 10 A/cm² in an embodiment, and between 500 volts to 1500 volts and in a range of frequencies of between about 100 Hz to 5 kHz.

Referring to FIG. 1B, a secondary positive pulse is applied after a short pause after the primary pulse, the pause between the secondary positive pulse and the primary negative pulse may range from 0 to 10 μs. In FIG. 1B-1D, the secondary pulse is illustrated as being applied between the third time t3 and fourth time t4 although there may be a short time gap (a pause like mentioned before, which is illustrated as occurring between time t2 and time t3) between the end of the primary pulse and the beginning of the secondary pulse in some embodiments.

The secondary pulse is positive and designed to force the dislodged metal atoms away from the target 30. The pulse width PW of the secondary pulse may be varied between alternate cycles so as to change at which target atoms are accelerated away from the target 30. Increasing the pulse width and pulse potential will likely accelerate the target atoms towards the substrate and result in an increase in deposition current, i.e., the deposition rate. A higher deposition rate will improve tool throughput thereby reducing wafer cost. On the other hand, the layer of metal deposited at a higher deposition rate may have a higher density and/or a higher intrinsic stress. Depositing a thick layer of such a metal layer may cause wafer bowing and increase defectivity and result in reduction in process yield. Therefore, embodiments of the application use an alternating cycle in which the pulse width/pulse potential of the secondary pulse in alternating cycles is varied. For example, in a first cycle, the pulse width of secondary pulse may be larger than the pulse width of the secondary pulse in a second cycle immediately following the first cycle. By alternating between two different process conditions for the secondary pulse, the deposition rate of the target atoms on the substrate may be controlled-layer-by-layer.

In various embodiments, the system may be driven in a self-sputtering mode. In such a mode, during the primary pulse, a portion of the dislodged material is ionized and pulled back to the target dislodging more material. The extinction of the plasma in between pulses will be reignited by the subsequent pulse. If ions are remaining from the prior pulse, they too may be accelerated during the primary pulse. Residual electrons may be accelerated by a subsequent primary pulse as well creating new ionizations. In some embodiments, the parameters of the primary pulse may also be changed. In most embodiments, only the parameters of the secondary pulse are changed as the dislodged target atoms (even if not deposited) from the primary pulse may be utilized in the next cycle to bombard the target during the subsequent primary pulse.

Accordingly, in various embodiments, the changes in the parameters for the primary and secondary pulses may result in generation of the sputtered target material having a higher ion/neutrals ratio. The high voltage, high current pulses at the low frequencies generate high peak power which assists in ionizing the sputtered atoms and increasing the coverage of the deposited film layer.

As will be described in further detail herein, the HiPIMS system 10 may be utilized to form one or more layers on the semiconductor substrate 20. For example, in some embodiments, the HiPIMS system 10 may be utilized to deposit one or more metal-containing hard mask layers on the semiconductor substrate 20. Moreover, the HiPIMS system 10 may be controlled to form such hard mask layers on the semiconductor substrate 20 having a controlled or tuned stress, which advantageously facilitates formation of metal-containing hardmask layers having a desired thickness but with reduced stress so the semiconductor substrate 20 is not damaged (e.g., by warpage or bowing) due to the formation of the hard mask layers.

FIG. 2 is a schematic diagram illustrating a HiPIMS pulse generation system 110 (which may be referred to herein as system 110). The system 110 may be operated as part of, or in conjunction with, the HiPIMS system 10 and may be utilized to generate high-voltage pulses supplied by power source 34 in FIG. 1. For example, the processing circuitry 60 may be configured to execute the software instructions stored in the memory 58 to control or tune a stress of a layer (such as a metal-containing hard mask layer) that is formed on the semiconductor substrate 20 during processing in the HiPIMS system 10. In some embodiments, the system 110 may be included as part of the HiPIMS system 10, for example, with the system 110 being at least partially implemented by the controller 56 in FIG. 1.

The system 110 illustrated in FIG. 2 is provided as an example system which may be utilized to form a metal-containing hard mask layer having alternating layers of metal layer with different density/intrinsic stress in accordance with one or more embodiments of the present disclosure. However, embodiments of the present disclosure are not limited to the system 110 illustrated in FIG. 2, and in various embodiments, the HiPIMS system 10 may include any control system operable to generate an ion beam having a controlled energy suitable to control or tune the stress of the layer formed on a semiconductor substrate, as described herein.

The system 110 may include any circuitry suitable for generating HiPIMS pulses for a magnetron plasma sputtering system (such as the system 10 shown in FIG. 1) that are tunable to control a stress of a layer deposited on a substrate. HiPIMS systems may be utilized, for example, to deposit a hard mask layer on a substrate. An advantage of HiPIMS systems is that layers, such as a hard mask layer, may be deposited on a substrate with a high degree of thickness control. For example, HiPIMS systems may be used to form a metal or metal-containing layer having a film thickness between about 400 nm and 1200 nm. However, formation of a metal-containing hard mask layer, such as a tungsten silicide (WSi) film, may be limited in conventional HiPIMS systems, as metal-containing hard mask layers or films have some stress (e.g., compressive stress) that may cause warping or bowing of the semiconductor substrate. In general, the stress of the metal-containing layer increases with increasing thickness of the layer. As such, metal-containing hard mask layers formed in a conventional HiPIMS system may be limited in thickness, and the processing of the substrate may thus be limited based on the limited thickness of the hard mask layers. However, in various embodiments of the present disclosure, the HiPIMS pulse generation system 110 facilitates precise control and tuning of the stresses of the deposited layer so that, for example, a WSi film may be formed having any thickness and with very little or no stress, and thus limited or no warpage or bowing of the semiconductor substrate.

In some embodiments, the system 110 includes primary pulse generation circuitry 182 and secondary pulse generation circuitry 183.

In some embodiments, the system 110 includes a primary power supply 152 which may be electrically coupled to a primary energy storage device 172. The primary power supply 152 may be any suitable power supply, and in some embodiments the primary power supply 152 is a negative DC power supply that outputs a negative DC voltage. The primary power supply 152 may output any suitable voltage, and in some embodiments, the primary power supply 152 outputs −1000 VDC. The primary energy storage device 172 stores electrical energy received from the primary power supply 152. The primary energy storage device 172 may include any suitable energy storage element, and in some embodiments, the primary energy storage device 172 includes one or more storage capacitors. The primary energy storage device 172 provides electrical energy to the primary pulse generation circuitry 182.

The primary pulse generation circuitry 182 may be or include any circuitry operable to generate and output an electrical pulse, for example, utilizing electrical power stored in the primary energy storage device 172. The primary pulse generation circuitry 182 may include pulse modulation circuit, function generator, matching circuit, timing circuit, and others needed to generate high voltage negative pulses. In some embodiments, the primary pulse generation circuitry 182 includes a plurality of transistors. The transistors may be arranged in any suitable configuration suitable to generate or output an electrical pulse based on energy supplied from the primary energy storage device 172. In some embodiments, the transistors may be high-voltage fast IGBTs. The primary pulse generation circuitry 182 may include driver circuitry configured to drive the transistors.

The system 110 further includes a secondary power supply 153. The secondary power supply 153 is electrically coupled to a secondary energy storage device 173. The secondary power supply 153 may be any suitable power supply, and in some embodiments the secondary power supply 153 is a positive DC power supply that outputs a positive DC voltage. The secondary power supply 153 may output any suitable voltage. The secondary energy storage device 173 stores electrical energy received from the secondary power supply 153, and may include any suitable energy storage element, such as one or more storage capacitors in some embodiments. The secondary energy storage device 173 provides electrical energy to the secondary pulse generation circuitry 183.

The secondary pulse generation circuitry 183 may be the same or similar as previously described with respect to the primary pulse generation circuitry 182. The secondary pulse generation circuitry 183 may include pulse modulation circuit, function generator, matching circuit, timing circuit, and others needed to generate high voltage positive pulses. For example, the secondary pulse generation circuitry 183 may be or include any circuitry operable to generate and output an electrical pulse, for example, utilizing electrical power stored in the secondary energy storage device 173. In some embodiments, the secondary pulse generation circuitry 183 includes a plurality of high-voltage fast IGBTs, which may be arranged in any suitable configuration suitable to generate or output an electrical pulse based on energy supplied from the secondary energy storage device 173. Additionally, in some embodiments, the secondary pulse generation circuitry 183 may include driver circuitry configured to drive the transistors of the secondary pulse generation circuitry 183.

The primary pulse generation circuitry 182 and the secondary pulse generation circuitry 183 may be configured to output primary pulses and secondary pulses, respectively, to an output line 194. The output line 194 may be coupled to the HiPIMS system 10 and utilized to supply the primary pulses and secondary pulses to the target electrode of the HiPIMS system 10 during processing of the semiconductor substrate 20. During deposition of metal layers, such as a tungsten or tungsten silicide hard mask layer, the positive secondary pulse can be controlled (e.g., by controlling voltage, pulse duration, or any other parameter) to form the layer having desired characteristics. For example, the deposited layer may be formed to have a desired stress profile by controlling the positive secondary pulse. In some embodiments, the system 110 may be utilized (for example, in conjunction with the HiPIMS system 10 shown in FIG. 1) to form a metallic hard mask layer on a semiconductor substrate having reduced stress (e.g., compressive or tensile stress) or no stress, thereby reducing or eliminating bowing or warping of the semiconductor substrate when the hard mask layer is formed.

In some embodiments, operations of the primary pulse generation circuitry 182 and the secondary pulse generation circuitry 183 are controlled by commands issued by the controller 56, which may be a microcontroller, a microprocessor, or any processing circuitry configured to perform the various functions described herein with respect to the controller 56.

The system 110 may include any additional features, elements, circuitry or the like suitable for controlling generation of the primary pulses and the secondary pulses, and thereby controlling formation of metal layers by the HiPIMS system 10. For example, in various embodiments, the system 110 may include protective circuits configured to protect the primary pulse generation circuitry 182 and the secondary pulse generation circuitry 183. The system 110 may further include monitoring circuitry, for example, for monitoring current, voltage, or any other electrical parameters of the system 110. In some embodiments, the system 110 includes output monitoring circuitry configured to monitor the electrical pulses that are output to the HiPIMS system 10. For example, electrical parameters may be monitored and utilized by the controller 56 to control or adjust the output primary pulses and secondary pulses.

Embodiments of the present disclosure are not limited to the HiPIMS pulse generation system 110 illustrated in FIG. 2, and in various embodiments, the HiPIMS pulse generation system 110 may include any circuitry operable to generate primary pulses and secondary pulses for controlling or tuning the stress of a metal-containing layer formed in the HiPIMS system 10. In some embodiments, the HiPIMS pulse generation system 110 may include a tunable impulse generator which may be, for example, based on an array of parallel-arranged high-current, fast power switches (e.g., IGBTs and MOSFETs) controlled by programmable logic or circuitry that facilitates sequential/serial switch firing to achieve high pulse frequencies at moderate peak currents, and simultaneous/parallel switch firing for achieving higher peak currents at lower frequencies to generate a plasma for material sputtering and etching. In some embodiments, the HiPIMS pulse generation system 110 may include configurable logic for sequential and synchronous output of a primary negative pulse and a positive secondary pulse with master/slave synchronization, timing delay and pulse adjustment.

In some embodiments, the system 110 includes ignition circuitry 192 which may provide electrical power to the output line 194, for example, for initial plasma ignition generation by the HiPIMS system 10.

The system 110 exhibits very low output inductance owing to the parallel circuit switching architecture and capacitive energy source storage. The low output inductance enables fast turn off at high currents, controlled voltage reversal, and application of an opposite polarity (e.g. positive electrical potential) secondary pulse after application of a primary (e.g. negative electrical potential) pulse.

As described herein, the system 110 may be utilized to generate HiPIMS pulses for a magnetron plasma thin-film sputtering system, such as the HiPIMS system 10 described with respect to FIG. 1, with a high degree of pulsing flexibility that permits tuning/configuration of the power supply circuitry that facilitates trading pulse frequency, pulse current and pulse duration. The HiPIMS pulse generation system 110 thus facilitates precise control of pulses delivered to the HiPIMS system 10, which allows for formation of layers, such as metal-containing hard mask layers, having a desired stress profile. For example, the layer may be formed to have no or low compressive stress to avoid warpage or bowing of the semiconductor substrate 20, even for relatively thick layers. More particularly, the secondary pulse generation circuitry 183 outputs a controlled electrical pulse that is delivered to the plasma in the HiPIMS system 10. The pulsed power facilitates generation of high currents and rapidly modifying a plasma potential near the magnetron sputtering gun of the HiPIMS system 10, which may be utilized to precisely control the stresses of a layer (e.g., a WSi hard mask layer) as it is formed in the HiPIMS system 10.

In some embodiments, one or more of the secondary pulse generation circuitry 187, the secondary energy storage device 173, or the secondary power supply 153 may be adjustable (e.g., by a user or by the controller 56) so that the positive secondary pulses may be output having a desired power level, for example, to deposit a layer having a desired stress profile. In some embodiments, the secondary pulse generation circuitry 183 generates a positive secondary pulse to the magnetron plasma discharge (after the fast termination of a primary negative pulse) to reverse the potential structure across the magnetic confinement zone and accelerate ions away from the target towards the substrate.

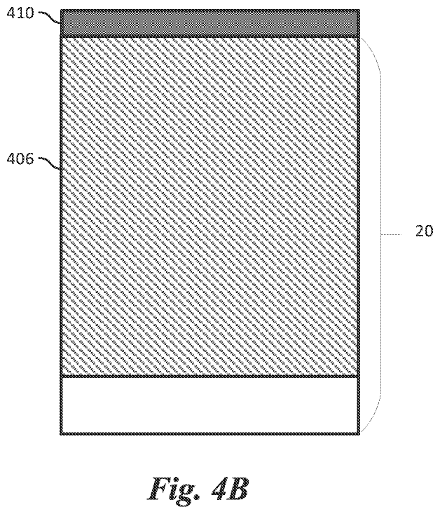

FIG. 3 is a structure zone diagram illustrating a relationship between stresses of a layer formed by plasma deposition (e.g., in a HiPIMS system) and temperature and energy for a given thickness.

Unlike conventional processes, embodiments are able to achieve the benefits of depositing higher quality films by controlling the kinetic energy of the ions, i.e., ion energy, using a secondary pulse. Specifically, the voltage of the secondary pulse controls the sheath drop, which controls the ion energy. These advantages may be achieved without independent substrate heating and hence the deposition may be performed at lower temperatures than typical PVD processes.

As illustrated in FIG. 3, the structure of the deposited material may be made to be different depending on the processing parameters such as temperature and energy. In FIG. 3, the x-axis represents the kinetic energy of atoms arriving at the substrate and y-axis represents the temperature of the substrate caused by the potential energy of the atoms arriving on the surface of the substrate.

As discussed in various embodiments, the primary and secondary pulse parameters may be varied which results in the variation of the temperature and kinetic energy, which enables deposition of tensile film to compressive films. This is because at low kinetic energy and low temperature, the deposited film is porous and higher in tensile stress while at higher kinetic energy and temperatures, the deposited film is denser and has compressive stress. Thus, the tensile and compressive stresses of the deposited layer may be varied based on these processing parameters. Accordingly, utilizing embodiments described herein, the tensile and compressive stresses of a layer formed in the HiPIMS system 10 may be controlled as desired, for example, by control of the pulses applied at the target electrode during the HiPIMS cycle.

In one or more embodiments, when a stable process has been identified, the pulse parameters such as a pulse width and pulse potential of the primary and secondary pulses may be held constant to achieve a specific target stress.

In certain embodiments, it may be easier to switch the pulse parameters such as a pulse width and pulse potential of the primary and secondary pulses between consecutive cycles so that the deposited layers alternate between slightly more tensile and slightly more compressive so that the stress of the film is effectively compensated and able to achieve a specific target stress. Such a process may potentially provide a higher throughput in certain embodiments, as well as potentially avoiding delamination of the film without the use of a spacer layer.

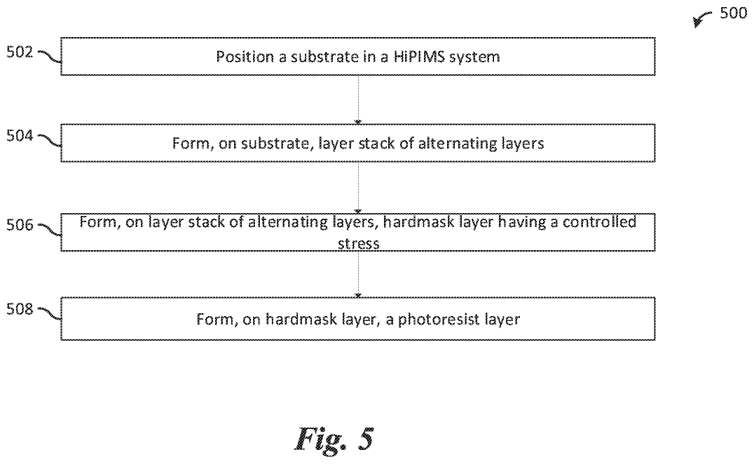

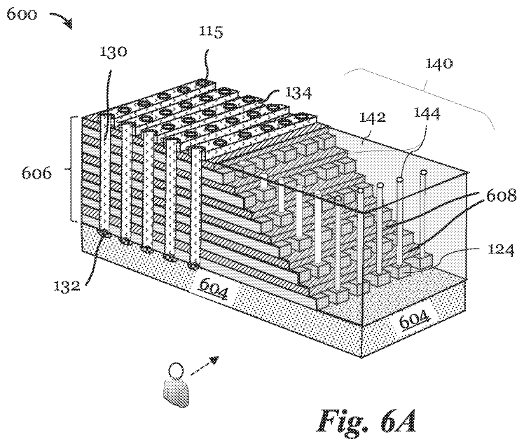

FIG. 4A is a flow chart illustrating a method 400, in accordance with some embodiments. FIG. 4B illustrates a cross-sectional view of a substrate with a hardmask layer formed in accordance with embodiments, e.g., described in FIG. 4A.

At box 402, a metal containing layer 410 is formed on a substrate 20 in a plasma processing chamber 12 of a HiPIMS system 10, as described above with respect to FIGS. 1 through 3. The substrate 20 may include a layer 406, which may comprise alternating layers (e.g., a layer stack), a layer of one material, or a combination of both in various embodiments. Examples of layer 406 may be a silicon oxide layer, alternating layers of oxide and nitride, alternating layers of silicon and silicon germanium.

The metal containing layer 410 includes a metal layer in one embodiment. In some embodiments, the metal containing layer is a tungsten layer, or a tungsten silicide layer, or any material layer suitable as a hardmask layer (e.g., carbides, silicides, nitrides, oxides, and most metals).

At box 404, forming the metal containing layer 410 may comprise controlling a stress of the metal containing layer 410 by controlling an ion energy in the plasma processing chamber 12 during the formation of the metal containing layer, as described above with respect to FIGS. 1 through 3. The stress may be a tensile stress or a compressive stress in various embodiments. The ion energy may be controlled, for example, by generating secondary pulses having specific pulse widths and/or pulse potential, which drive ions of the target 30 to a surface of the substrate 20. As described in various embodiment, the secondary pulses are applied after applying primary pulses of an opposite polarity.

In certain embodiments, the forming of the metal containing layer 410 may include applying a cyclic plurality of pulses, each cycle comprising applying a primary negative pulse on a target electrode to dislodge target atoms from the target electrode and a secondary positive pulse to accelerate the dislodged target atoms towards the substrate. In an embodiment, a primary negative pulse width may be on the order of 2 times to 20 times the pulse width of the secondary positive pulse, and both may vary widely in this range. In an example embodiment, a primary pulse is in the range of 50-150 μs, and a secondary pulse is in the range of 5-15 μs. In other embodiments, the secondary pulse may be in the range of 5-150 μs without extinguishing the plasma. In certain embodiments, the secondary positive pulse in one of the cycles is different from the secondary positive pulse in another one of the cycles. In an embodiment, the secondary positive pulse in one of the cycles has a different pulse width than the secondary positive pulse in another one of the cycles. In an embodiment, a pulse width of the one of the cycles is 1.5 times to 3 times the pulse width of another one of the cycles. In an embodiment, the secondary positive pulse in one of the cycles has a different pulse potential than the secondary positive pulse in another one of the cycles. In an embodiment, the metal containing layer comprises a thickness of 10 nm to 1000 nm.

In an embodiment, one of the cycles deposits a first layer of the metal containing layer 410 at a first density and another one of the cycles deposits a second layer of the metal containing layer at a second density different from the first density. In an embodiment, after depositing the metal containing layer, the metal containing layer comprising a stack of alternating first layer and second layer. In an embodiment, the first layer is 0.2 nm to 20 nm, and the second layer is 0.2 nm to 20 nm. In certain embodiments, the first and second layers may be monolayers.

In an embodiment, one of the cycles deposits a first layer of the metal containing layer 410 at a first intrinsic stress and another one of the cycles deposits a second layer of the metal containing layer at a second intrinsic stress different from the first intrinsic stress. In an embodiment, the first intrinsic stress is compressive and the second intrinsic stress is tensile. In an embodiment, after depositing the metal containing x layer, the metal containing layer comprising a stack of alternating first layer and second layer. In an embodiment, the first layer is 0.2 nm to 20 nm, and the second layer is 0.2 nm to 20 nm.

In various embodiments, the metal containing layer 410 comprises a hardmask layer.

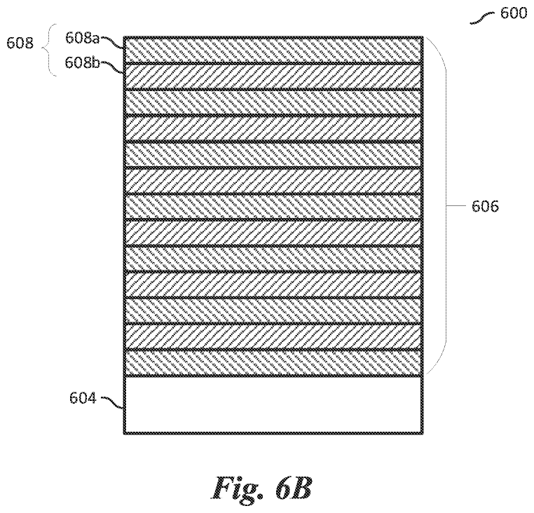

FIG. 5 illustrates a process flow chart diagram of a method 500 for manufacturing a semiconductor structure, in accordance with some embodiments.

At box 502, a substrate 20 is positioned into a plasma processing chamber 12 of a HiPIMS system 10, as described above with respect to FIG. 1. At box 504, a dielectric stack is formed on the substrate 20, which needs to be patterned with a high aspect ratio feature such as contact hole. While this embodiment describes the formation of a mask layer for a contact hole as an example, embodiments may also be used to form masking layers for trenches and other types of features as well. At box 506, a hard mask layer is formed having a controlled stress on a surface of the substrate 20. The hard mask layer may be, for example, a metal-containing hard mask layer such as a WSi layer. Forming the hard mask layer having a controlled stress may include generating a first pulse having a first polarity and driving ions off a metal target to the surface of the substrate by generating and applying a secondary pulse and having a second polarity opposite the first polarity. The generating and the driving are repeated to form the film.

In certain embodiments, the secondary pulse has a different pulse parameter when repeating the driving.

Advantageously, the hard mask layer thus formed has a lower stress than a typical hardmask layer. A photoresist layer may be formed over the hardmask layer (box 508) and developed followed by patterning of the hardmask layer and subsequent formation of openings within the layer stack.

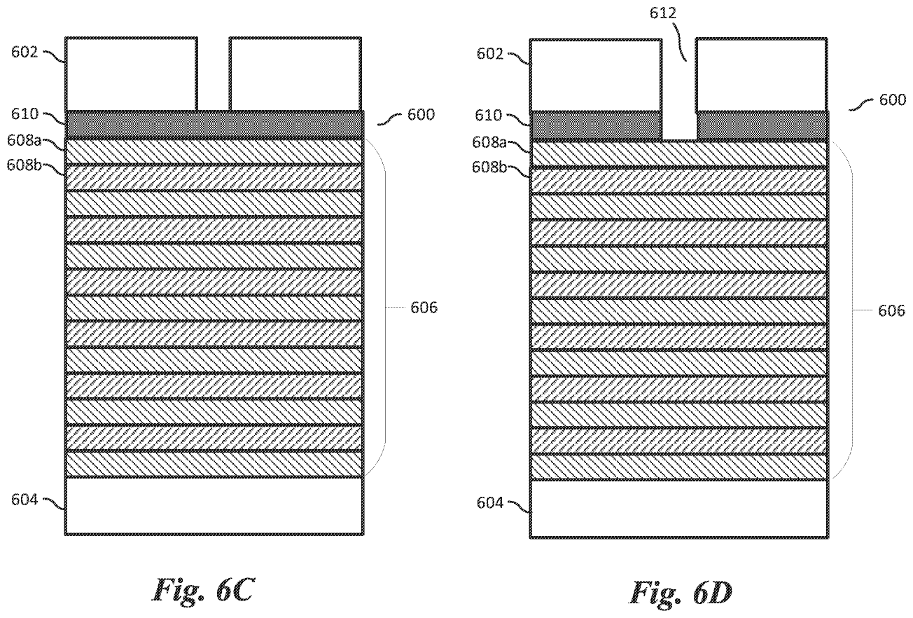

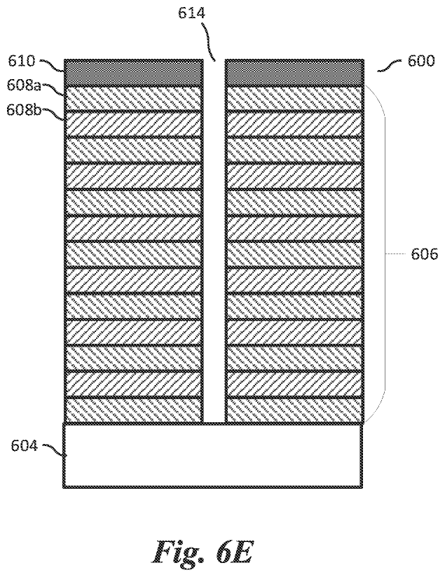

FIG. 6A illustrates a three dimensional (3D) isometric projection view of a 3D semiconductor structure 600 with a staircase structure 140 in accordance with various embodiments.

To clarify the process being described in FIGS. 6B-6E, a partial three-dimensional isometric projection view of the semiconductor structure 600, e.g., a 3D NAND memory array being fabricated over a substrate 604 is illustrated in FIG. 6A. The structure illustrated in FIG. 6A is only for example and some portions (e.g., transistor channel material) are not illustrated in FIG. 6A. Although this embodiment is illustrated using charge trapping flash (CTF) transistors, embodiments may also be applied to 3D NAND technology made with floating gate technology.

In various embodiments, the substrate 604 may be a silicon wafer, or a silicon-on-insulator (SOI) wafer. In certain embodiments, the substrate 604 may comprise a silicon germanium wafer, silicon carbide wafer, gallium arsenide wafer, gallium nitride wafer and other compound semiconductors. In other embodiments, the substrate 604 comprises heterogeneous layers such as silicon germanium on silicon, gallium nitride on silicon, silicon carbon on silicon, as well layers of silicon on a silicon or SOI substrate. In various embodiments, the substrate 604 is patterned or embedded in other components of the semiconductor device.

As illustrated in FIG. 6A, the substrate 604 may comprise a 3D NAND dielectric stack 606 comprises alternating dielectric layers 608 such as silicon oxide and a series of word lines 124. In certain embodiments, the word lines 124 may comprise a refractory metal such as tungsten (W), molybdenum (Mo), and ruthenium (Ru). Process flow to form the word lines 124 may include first forming a layer stack comprising the dielectric layers 608 and a sacrificial dielectric layer such as silicon nitride, followed by replacing the sacrificial dielectric layer with a conductive material to form the word lines 124. Although the 3D NAND dielectric stack 606 is shown to include a particular number of layers, the 3D NAND dielectric stack 606 may include as few as two layers and upwards of one-hundred layers or more. In one or more embodiments, the 3D NAND dielectric stack 606 may be used to fabricate 32- or 48-layer NAND memory devices. The number of layers expected to be a part of the 3D NAND dielectric stack 606 likely will continue to increase over time to provide larger and larger 3D NAND memory devices, and the methods of this disclosure may be applied to such large stack structures as well.

Charge trapping flash (CTF) transistors are formed on the sidewalls of high aspect ratio channel openings 115 formed through the 3D NAND dielectric stack 606. A CTF transistor gate dielectric such as oxide/nitride/oxide (ONO) is deposited on the sidewalls of the high aspect ratio channel openings 115. Over the CTF transistor gate dielectric, CTF transistor channel material 130 such as polysilicon is deposited. Each 3D NAND CTF transistor is separated vertically from adjacent CTF transistors by horizontal layers of dielectric 122. The word lines 124 is coupled to the gates of individual transistors, where a voltage may be applied to turn on the channel of the corresponding CTF transistor. The CTF transistor channel material 130 electrically contacts a first bit line 132 (transistor source) in the substrate 604 at the bottom of the high aspect ratio channel opening 115 and contacts a second bit line 134 (transistor drain) on the top end of the high aspect ratio channel opening 115. The bit lines 132 and 134 run perpendicular to the word lines 124.

Still referring to FIG. 6A, the substrate 604 may further comprise the staircase structure 140 where multi-level contacts (MLC) 144 may be formed using a highly selective MLC etch process in accordance with various embodiments. The staircase structure 140 is designed to allow an electrical contact to be formed for each of the word lines 124 from different layers within the 3D NAND dielectric stack 606. Accordingly, the MLC 144 comprises contacts with different lengths to reach different layers of the word lines 124 as illustrated in FIG. 6. For illustration purpose, only some contacts of the MLC 144 are illustrated. As illustrated in FIG. 6, the 3D NAND dielectric stack 606 is covered by a pre-metal dielectric (PMD) layer 142. In various embodiments, the PMD layer 142 has a thickness approximately same as the thickness of the 3D NAND dielectric stack 606. Contact holes for the MLC 144 are etched through the thick PMD layer 190 stopping on the word lines 124. These contact holes can be filled with metal to provide electrical connection between the word lines 124 and overlying metal interconnect leads (not shown).

This process flow of forming the above structure will be further described below referring to FIGS. 6B-6F in accordance with various embodiments.

FIGS. 6B-6E illustrate cross-sectional views of an example substrate 604 during various stages of fabricating a semiconductor structure 600 in accordance with various embodiments. This embodiment will describe the formation of a high aspect ratio feature for forming a 3D NAND device although embodiments may be applied for any other such high aspect ratio features.

Referring now to FIG. 6B, a substrate 604 is prepared for the deposition of the various semiconducting layers of a semiconductor structure 600. Substrate 604 may include any substrate material(s) suitable for use in forming a semiconductor device. For example, substrate 604 may include a semiconductor substrate such as a silicon substrate, a silicon-on-insulator substrate, and heterostructures, and in certain embodiments may include various device and isolation regions formed therein.

A dielectric stack 606 of alternating material layers is deposited over the substrate 604. In an embodiment, this forms the 3D NAND dielectric stack of the 3D NAND devices. Initially, dielectric stack 606 includes alternating layers 608a and 608b, which may be referred to collectively as layers 608, of oxide (e.g., silicon dioxide (SiO₂)) and nitride (e.g., silicon nitride (SiN)), respectively. Although dielectric stack 606 is shown to include a particular number of layers 608, dielectric stack 606 may include any suitable number of layers depending on the technology and other requirements. The layer stack may be formed by repeatedly depositing layers in an alternating arrangement using a chemical vapor deposition (CVD) process, a plasma-enhanced CVD (PECVD) process, a physical vapor deposition (PVD) process, or a plasma-enhanced PVD (PEPVD) process. Each instance of performing the deposition process stresses the semiconductor structure being formed, such as producing high internal stress.

After a predetermined number of alternating layers 608a and 608b have been deposited as dielectric stack 606, a hardmask layer 610 may be deposited on top of dielectric stack 606.

FIG. 6C illustrates the substrate 604 after depositing the hardmask layer 610 on top of dielectric stack 606 and forming a patterned photoresist stack in accordance with embodiments of the present disclosure.

The HiPIMS system of FIG. 1A may be used to control the stress of the hardmask layer 610 being deposited. For example, the deposition of the hardmask layer 610 may be performed as described in more details in the embodiments of FIGS. 1-5.

The hardmask layer 610 may be used as an etch mask for subsequent etch steps. Hardmask layer 610 may include a material suitable for use in the etch process to be performed. In various embodiments, the hardmask layer 610 is deposited using the HiPIMS system while controlling the ion energy so as to control the stress within the hardmask layer 610 being deposited. Advantageously, by reducing the stress of the hardmask layer 610, the bowing of the substrate 604 may be reduced significantly. For example, as described above, the deposition may be performed by performing a plurality of cycles, each cycle comprising a sequence of pulses applied on the target electrode, for example. For example, each cycle may include a primary negative pulse, which causes ions from the plasma to be accelerated towards the target electrode, which in turn increases the number of target atoms being dislodged from the target electrode. The secondary positive pulse may then be applied to accelerate the dislodged target atoms towards the substrate. In certain embodiments, the secondary pulse in one of the cycles is different from the secondary pulse in another one of the cycles so as to change the ion energy during the deposition cycle. For example, the secondary pulse in one of the cycles has a different pulse width than the secondary pulse in another one of the cycles. In another embodiment, the secondary pulse in one of the cycles has a different pulse potential than the secondary pulse in another one of the cycles.

In an embodiment, one of the cycles deposits a first layer of the hardmask layer 610 at a first intrinsic stress and the another one of the cycles deposits a second layer of the hardmask layer 610 at a second intrinsic stress different from the first intrinsic stress. For example, the first intrinsic stress is compressive and the second intrinsic stress is tensile. By alternating different stress within the hardmask layer 610 that is being formed, the overall stress of the hardmask layer 610 can be made more neutral or effectively lowered.

In an embodiment, one of the cycles deposits a first layer of the metal containing hardmask layer at a first density and another one of the cycles deposits a second layer of the metal containing hardmask layer at a second density different from the first density. For example, the first density may be less than the second density. The differences in density may cause the associated intrinsic stress of the material being deposited to be different. By alternatively forming different density layers within the hardmask layer 610, the overall stress of the hardmask layer 610 can be made more neutral or effectively lowered.

In various embodiments, the hardmask layer 610 is at least 100 nm, and at least 500 nm in some embodiments. In some embodiments, the hard mask layer 610 has a thickness that may vary between less than 10 nm and up to greater than 1 μm in various embodiments. Despite the thick hard mask being deposited, the intrinsic stress of the hardmask layer 610 is significantly lower than a conventional hardmask layer deposited using conventional magnetron sputtering without HiPIMS and therefore results in less bowing. A reduction in bowing can help minimize across wafer defects as well as stress induced defects that can traverse across the wafer and/or into the substrate during subsequent processing.

In various embodiments, the density of the material within the hardmask layer 610 varies through the thickness of the hardmask layer 610. In one or more embodiments, the hardmask layer 610 may comprise alternating layers of high/low density layers of the hard mask material. In one or more embodiments, the lower density layer may be 20% to 40% less dense than the higher density layer of the hardmask layer 610.

In various embodiments, the hardmask layer 610 may comprise a metal containing layer. In various embodiments, hardmask layer 610 comprises tungsten, tantalum, ruthenium, hafnium, aluminum, and others. In various embodiments, hardmask layer 610 may comprise metal oxide, metal nitride, or metal silicide. In certain embodiments, hardmask layer 610 comprises tungsten silicide (WSi). In certain embodiments, the hardmask layer 610 may also comprise a liner layer such as a nitride layer.

A photoresist layer 602 may be deposited over the hardmask layer 610 and patterned using conventional photolithographic techniques. In one or more embodiments, the photoresist layer 602 may be patterned to form holes. In certain embodiments, the photoresist layer 602 may be patterned to form trenches. In either case, a photo mask is aligned so that the holes are produced at the desired locations.

FIG. 6D illustrates the substrate 604 after the initial etching process of beginning to expose the photoresist layer 602 to light which activates the photoresist layer and starts the etching process for the regions of the semiconductor structure that is exposed to light (hence the regions that are not covered by the hardmask layer).

The hardmask layer 610 is patterned to form openings 612 using the photoresist layer 602 as an etch mask. In various embodiments, the patterning of the hardmask layer 610 may be performed using an anisotropic etching process such as a plasma etch process.

FIG. 6E illustrates the substrate 604 after etching through the layer stack in accordance with embodiments of the present disclosure.

As shown in FIG. 6E, openings 614 are formed in dielectric stack 606 using the hardmask layer 610 as an etch stack. Hardmask layer 610 is relatively immune from etching and thus prevents the etch chemistry from etching through the hardmask layer 610 resulting in vertical sidewalls for the openings 614. In the illustrated example, openings 614 are formed through dielectric stack 606 until a surface of substrate 604 is exposed. As previously noted, openings 614 may be holes, trenches, vias, or any other suitable type(s) of openings. In certain embodiments, openings 614 are referred to as slits that ultimately will be used to deposit conductive material for one or more gates of a 3D semiconductor device under construction (e.g., of a 3D memory device, such as a 3D vertical NAND device).

In various embodiments, the openings 614 are high aspect ratio (HAR) features. Features with aspect ratio (ratio of height of the feature to the width of the feature) higher than 20:1 are generally considered to be high aspect ratio features, and in various embodiments, some of the openings 614 may have at least such an aspect ratio. In one embodiment, the openings 614 may have an aspect ratio between 40:1 and 100:1. In certain embodiments, the openings 614 may have a depth from 5 μm and 20 μm, and the etch process may etch the hardmask layer 610 for more than 5 μm in depth. Advantageously, the etch process in various embodiments may achieve such HAR features with a total process time of less than 1 hour.

Subsequent processing may be performed to form the device described in FIG. 6A. Although not described specifically, embodiments of forming the contact holes for forming the multi-level contacts (MLC) 144 may also use the HiPIMS system and deposition process to deposit a lower stress metal containing hard mask layer.

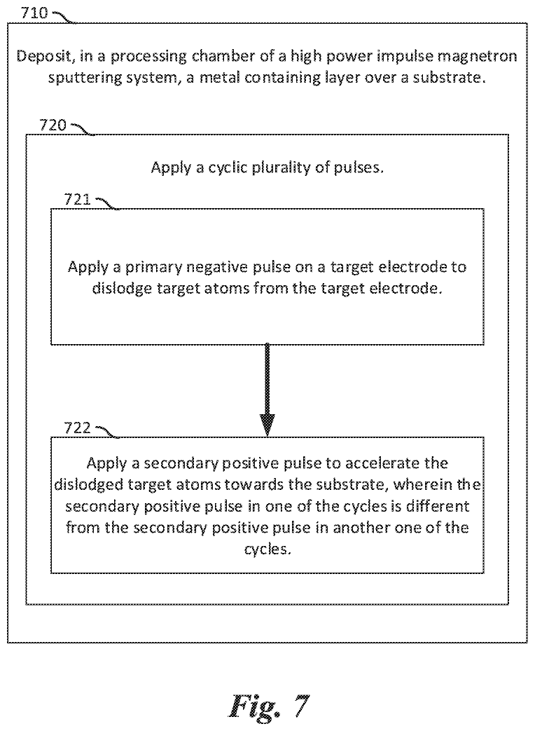

FIG. 7 is a flow chart illustrating embodiments of the present disclosure.

In an embodiment, a method includes depositing, in a processing chamber of a high-power impulse magnetron sputtering system, a metal containing layer over a substrate (box 710). Which may be accomplished by applying a cyclic plurality of pulses (box 720). The cyclic plurality of pulses comprises first applying a primary negative pulse on a target electrode to dislodge target atoms from the target electrode (box 721), and then applying a secondary positive pulse to accelerate the dislodged target atoms towards the substrate, wherein the secondary positive pulse in one of the cycles is different from the secondary positive pulse in another one of the cycles (box 722).

The various boxes described above may be implemented as further described using FIG. 4A and FIG. 5 above. For example, in an embodiment, box 710 may be implemented as box 404 in FIG. 4A and box 506 in FIG. 5.

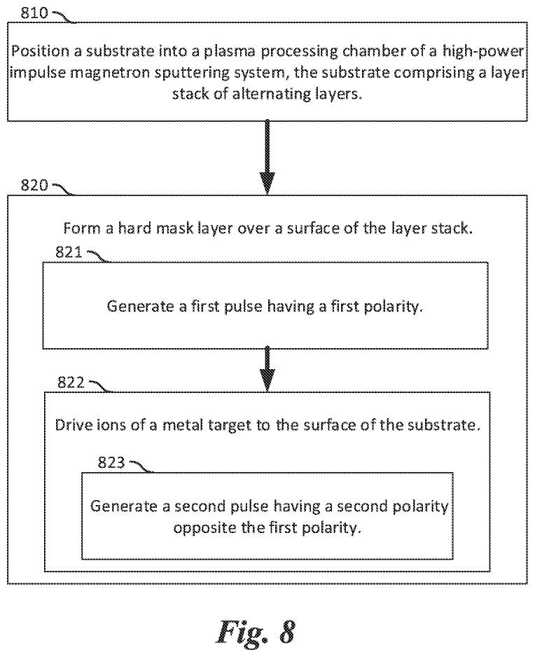

FIG. 8 is a flow chart illustrating embodiments of the present disclosure.

In an embodiment, a method includes positioning a substrate into a plasma processing chamber of a high-power impulse magnetron sputtering system, the substrate comprising a layer stack of alternating layers (box 810). The method then includes forming a hard mask layer over a surface of the layer stack (box 820). This is accomplished by first generating a first pulse having a first polarity (box 821), and then driving ions of a metal target to the surface of the substrate (box 822). Driving the metal ions of a metal target to the surface of the substrate is accomplished by generating a second pulse having a second polarity opposite the first polarity (box 823).

The various boxes described above may be implemented as further described using FIGS. 4A and 5 above. For example, in an embodiment, box 810 may be implemented as box 502, and box 820 may be implemented as box 402 of FIG. 4A and box 506 in FIG. 5.

Example embodiments of the invention are described below. Other embodiments can also be understood from the entirety of the specification as well as the claims filed herein.
Example 1. A method includes depositing, in a processing chamber of a high-power impulse magnetron sputtering system, a metal containing layer over a substrate. The depositing includes applying a cyclic plurality of pulses. Each cycle includes applying a primary negative pulse on a target electrode to dislodge target atoms from the target electrode and a secondary positive pulse to accelerate the dislodged target atoms towards the substrate. The secondary positive pulse in one of the cycles is different from the secondary positive pulse in another one of the cycles.
Example 2. The method of example 1, where the secondary positive pulse in one of the cycles has a different pulse width than the secondary positive pulse in another one of the cycles.
Example 3. The method of one of examples 1 or 2, where a pulse width of the one of the cycles is 1.5 times to 20 times the pulse width of the another one of the cycles.
Example 4. The method of one of examples 1 to 3, where the secondary positive pulse in one of the cycles has a different pulse potential than the secondary positive pulse in another one of the cycles.
Example 5. The method of one of examples 1 to 4, where the metal containing layer includes a thickness of less than 10 nm to greater than 1 μm.
Example 6. The method of one of examples 1 to 5, where one of the cycles deposits a first layer of the metal containing layer at a first density and the another one of the cycles deposits a second layer of the metal containing layer at a second density different from the first density.
Example 7. The method of one of examples 1 to 6, where after depositing the metal containing layer, the metal containing layer includes a stack of alternating first layer and second layer.
Example 8. The method of one of examples 1 to 7, where the first layer is less than 10 nm to greater than 1 μm, and the second layer is less than 10 nm to greater than 1 μm.
Example 9. The method of one of examples 1 to 8, where one of the cycles deposits a first layer of the metal containing layer at a first intrinsic stress and the another one of the cycles deposits a second layer of the metal containing layer at a second intrinsic stress different from the first intrinsic stress.
Example 10. The method of one of examples 1 to 9, where the first intrinsic stress is compressive and the second intrinsic stress is tensile.
Example 11. The method of one of examples 1 to 10, where after depositing the metal containing layer, the metal containing layer includes a stack of alternating first layer and second layer.
Example 12. The method of one of examples 1 to 11, where the first layer is less than 10 nm to greater than 1 μm, and the second layer is less than 10 nm to greater than 1 μm.
Example 13. A method for manufacturing a semiconductor structure includes positioning a substrate into a plasma processing chamber of a high-power impulse magnetron sputtering system. The substrate includes a layer stack of alternating layers. The method includes forming a hard mask layer over a surface of the layer stack, where the forming includes generating a first pulse having a first polarity; and driving ions of a metal target to the surface of the substrate by generating a second pulse having a second polarity opposite the first polarity.
Example 14. The method of example 13, further including: repeating the generating and the driving, the second pulse having a different pulse parameter during the repeating.
Example 15. The method of one of examples 13 or 14, where the metal target includes tungsten.
Example 16. The method of one of examples 13 to 15, where the substrate is a silicon substrate and the forming the hard mask layer includes forming a tungsten silicide film on the surface of the substrate.
Example 17. The method of one of examples 13 to 16, where the forming the hard mask layer includes forming a plurality of layers having alternating densities.
Example 18. The method of one of examples 13 to 17, where the forming the hard mask layer includes forming a plurality of layers having alternating intrinsic stress.
Example 19. A high-power impulse magnetron sputtering (HiPIMS) system includes a plasma processing chamber; and a substrate support in the plasma processing chamber. The substrate support is configured to hold a semiconductor substrate. The HiPIMS system includes pulse generation circuitry configured to supply positive and negative electrical pulses to the plasma processing chamber; and processing circuitry configured to apply a cyclic plurality of electrical pulses to a target electrode. Each cycle includes a primary negative pulse to dislodge target atoms from the target electrode and a secondary positive pulse to accelerate the dislodged target atoms towards the substrate support, where the processing circuitry configured to vary a pulse parameter of a secondary positive pulse in one of the cycles to a pulse parameter of a secondary positive pulse in another one of the cycles.
Example 20. The HiPIMS system of example 19, where the secondary positive pulse in one of the cycles has a different pulse width than the secondary positive pulse in another one of the cycles.
Example 21. The HiPIMS system of one of examples 19 or 20, where the secondary positive pulse in one of the cycles has a different pulse potential than the secondary positive pulse in another one of the cycles.
Example 22. The HiPIMS system of one of examples 19 to 21, where the processing circuitry is configured to control a intrinsic stress of a layer being deposited by controlling the primary negative and secondary positive pulses.
Example 23. The HiPIMS system of one of examples 19 to 22, where the pulse generation circuitry includes: a main pulse power supply configured to supply a negative voltage for the primary negative pulse; a primary energy storage device coupled to the main pulse power supply and configured to store electrical energy supplied from the main pulse power supply; primary pulse generation circuitry coupled to the primary energy storage device and configured to generate the primary negative pulse based on the electrical energy stored in the primary energy storage device; a kick pulse power supply configured to supply a positive voltage; a kick pulse energy storage device coupled to the kick pulse power supply and configured to store electrical energy supplied from the kick pulse power supply; and kick pulse generation circuitry coupled to the kick pulse energy storage device and configured to generate the secondary positive pulse based on the electrical energy stored in the kick pulse energy storage device.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method, comprising:
depositing, in a processing chamber of a high-power impulse magnetron sputtering system, a metal containing layer over a substrate, the depositing comprising applying a cyclic plurality of pulses, each cycle comprising
a primary negative pulse on a target electrode to dislodge target atoms from the target electrode and
a secondary positive pulse to accelerate the dislodged target atoms towards the substrate, wherein the secondary positive pulse in one of the cycles is different from the secondary positive pulse in another one of the cycles.

2. The method of claim 1, wherein the secondary positive pulse in one of the cycles has a different pulse width than the secondary positive pulse in another one of the cycles.

3. The method of claim 2, wherein a pulse width of the one of the cycles is 1.5 times to 20 times the pulse width of the another one of the cycles.

4. The method of claim 1, wherein the secondary positive pulse in one of the cycles has a different pulse potential than the secondary positive pulse in another one of the cycles.

5. The method of claim 1, wherein one of the cycles deposits a first layer of the metal containing layer at a first density and the another one of the cycles deposits a second layer of the metal containing layer at a second density different from the first density.

6. The method of claim 5, wherein after depositing the metal containing layer, the metal containing layer comprises a stack of alternating first layer and second layer.

7. The method of claim 1, wherein one of the cycles deposits a first layer of the metal containing layer at a first intrinsic stress and the another one of the cycles deposits a second layer of the metal containing layer at a second intrinsic stress different from the first intrinsic stress.

8. The method of claim 7, wherein the first intrinsic stress is compressive and the second intrinsic stress is tensile.

9. The method of claim 7, wherein after depositing the metal containing layer, the metal containing layer comprises a stack of alternating first layer and second layer.

10. A method for manufacturing a semiconductor structure, the method comprising:
positioning a substrate into a plasma processing chamber of a high-power impulse magnetron sputtering system, the substrate comprising a layer stack of alternating layers;
forming a hard mask layer over a surface of the layer stack, the forming comprising:
generating a first pulse having a first polarity; and
driving ions of a metal target to the surface of the substrate by generating a second pulse having a second polarity opposite the first polarity.

11. The method of claim 10, further comprising:
repeating the generating and the driving, the second pulse having a different pulse parameter during the repeating.

12. The method of claim 10, wherein the metal target includes tungsten.

13. The method of claim 12, wherein the substrate is a silicon substrate and the forming the hard mask layer includes forming a tungsten silicide film on the surface of the substrate.

14. The method of claim 10, wherein the forming the hard mask layer includes forming a plurality of layers having alternating densities.

15. The method of claim 10, wherein the forming the hard mask layer includes forming a plurality of layers having alternating intrinsic stress.

16. A high-power impulse magnetron sputtering (HiPIMS) system comprising:
a plasma processing chamber;
a substrate support in the plasma processing chamber, the substrate support configured to hold a semiconductor substrate;
pulse generation circuitry configured to supply positive and negative electrical pulses to the plasma processing chamber; and
processing circuitry configured to apply a cyclic plurality of electrical pulses to a target electrode, each cycle comprising a primary negative pulse to dislodge target atoms from the target electrode and a secondary positive pulse to accelerate the dislodged target atoms towards the substrate support, wherein the processing circuitry configured to vary a pulse parameter of a secondary positive pulse in one of the cycles to a pulse parameter of a secondary positive pulse in another one of the cycles.

17. The HiPIMS system of claim 16, wherein the secondary positive pulse in one of the cycles has a different pulse width than the secondary positive pulse in another one of the cycles.

18. The HiPIMS system of claim 16, wherein the secondary positive pulse in one of the cycles has a different pulse potential than the secondary positive pulse in another one of the cycles.

19. The HiPIMS system of claim 16, wherein the processing circuitry is configured to control a intrinsic stress of a layer being deposited by controlling the primary negative and secondary positive pulses.

20. The HiPIMS system of claim 16, wherein the pulse generation circuitry includes:
a main pulse power supply configured to supply a negative voltage for the primary negative pulse;
a primary energy storage device coupled to the main pulse power supply and configured to store electrical energy supplied from the main pulse power supply;
primary pulse generation circuitry coupled to the primary energy storage device and configured to generate the primary negative pulse based on the electrical energy stored in the primary energy storage device;
a kick pulse power supply configured to supply a positive voltage;
a kick pulse energy storage device coupled to the kick pulse power supply and configured to store electrical energy supplied from the kick pulse power supply; and
kick pulse generation circuitry coupled to the kick pulse energy storage device and configured to generate the secondary positive pulse based on the electrical energy stored in the kick pulse energy storage device.
